(19) United States
(12) Patent Application Publication
(10) Pub. No.: US 2026/0025960 A1
(43) Pub. Date: Jan. 22, 2026

(54) REGULATING COMPUTER SERVER RACK ACOUSTIC LEVELS

(71) Applicant: INTERNATIONAL BUSINESS MACHINES CORPORATION, ARMONK, NY (US)

(72) Inventors: Colin Edward MASTERSON, Rochester, MN (US); GUNNAR MILLS, Salt Lake City, UT (US); John R. Dangler, Rochester, MN (US); Joseph William Keegan, Apple Valley, MN (US)

(21) Appl. No.: 18/776,476

(22) Filed: Jul. 18, 2024

(51) Int. Cl. H05K 7/20

(52) U.S. Cl. CPC H05K 7/20836; H05K 7/20736

(57) ABSTRACT

According to one embodiment, a method, computer system, and computer program product for regulating acoustic levels produced within computer server racks is provided. The present invention may include adjusting a speed of one or more air moving devices to a configurable speed limit so that the computer server racks, in combination, produce an acoustic level below a set decibel threshold; receiving confirmation upon each of the air moving devices running at the configurable speed limit from one or more service processors in the computer servers; maintaining the running of the one or more air moving devices at the configurable speed limit during a duration that one or more acoustic rack doors are open; and adjusting the speed of the air moving devices back to their routine operating speeds upon receiving a lock request.

### BACKGROUND

The present invention relates, generally, to the field of computing, and more particularly to server management.

Server management involves monitoring and maintaining servers to ensure they operate reliably and at optimal performance levels. Additionally, server management involves the reduction of noise emitted by the servers in a server rack, such as by their cooling fans and spinning hard drives. Acoustic rack doors and covers can be used to attenuate external exposure to the acoustic levels generated by the computer servers within the computer server rack.

### SUMMARY

Embodiments of a method, a computer system, and a computer program product for regulating acoustic levels produced within one or more computer server racks are described. According to one embodiment, a method, computer system, and computer program product for regulating acoustic levels produced within one or more computer server racks may include adjusting a speed of one or more air moving devices to a configurable speed limit so that the one or more computer server racks, in combination, produce an acoustic level below a set decibel threshold, wherein the one or more air moving devices are located in one or more computer servers within the one or more computer server racks; receiving confirmation upon each of the one or more air moving devices running at the configurable speed limit from one or more service processors in the one or more computer servers; maintaining the running of the one or more air moving devices at the configurable speed limit during a duration that one or more acoustic rack doors are open, wherein the one or more acoustic rack doors are operationally coupled to the one or more computer server racks; and adjusting the speed of the one or more air moving devices back to their routine operating speeds upon receiving a lock request.

### BRIEF DESCRIPTION OF THE SEVERAL VIEWS OF THE DRAWINGS

These and other objects, features, and advantages of the present invention will become apparent from the following detailed description of illustrative embodiments thereof, which is to be read in connection with the accompanying drawings. The various features of the drawings are not to scale as the illustrations are for clarity in facilitating one skilled in the art in understanding the invention in conjunction with the detailed description. In the drawings:

FIG. 1 illustrates an exemplary networked computer environment according to at least one embodiment.

FIG. 2 depicts a block diagram of the components of a computer server rack acoustic levels regulation system according to at least one embodiment.

FIG. 3 is an operational flowchart illustrating a computer server rack acoustic levels regulating process according to at least one embodiment.

FIG. 4 is an operational flowchart illustrating an alternate computer server rack acoustic levels regulating process according to at least one embodiment.

FIG. 5 depicts a lookup table of a computer server's acoustic output in a computer server rack comprising one computer server according to at least one embodiment.

FIG. 6 depicts a lookup table of a second computer server's acoustic output in a computer server rack comprising multiple computer servers according to at least one embodiment.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

It is to be understood that the singular forms “a,” “an,” and “the” include plural referents unless the context clearly dictates otherwise. Thus, for example, reference to “a component surface” includes reference to one or more of such surfaces unless the context clearly dictates otherwise.

Embodiments of the present invention relate generally to the field of computing, and in particular to server management. The present embodiment has the capacity to improve the attenuation of external exposure to acoustic levels produced by computer servers within a computer server rack while the computer server rack's acoustic rack door is both closed and opened. The present embodiment can use a computer server rack system in collaboration with interlocking door hardware to set and control the locking status of a computer server rack's acoustic rack door. Additionally, the present embodiment can adjust the speed of the air moving devices in the computer servers to reduce external acoustic exposure from the computer server rack.

Currently, external exposure to the acoustic levels generated by computer servers in a computer server rack is reduced by wearing personal protective equipment (“PPE”), such as hearing protection, and the use of acoustic rack doors coupled to the computer server rack. However, PPE has a practical upper limit of the acoustic noise that it can safely block. Also, there is the possibility of dislodgement of the PPE in which full exposure to the acoustic levels would occur. Additionally, when maintenance needs to be performed on the computer servers inside the rack, the acoustic rack door is required to be opened, thereby increasing the exposure to the acoustic levels generated by the computer servers. As the density and power of computing hardware have continued to grow, the air moving devices, such as fans or blowers, required to drive airflow have become more powerful and as a result, produce higher acoustic levels. At the heightened acoustic levels produced inside the computer server rack, only a minimal duration of exposure is needed before hearing loss/damage can occur. Therefore, an implementation of a computer server rack system that can reduce the acoustic levels produced inside a computer server rack based on configuring a speed limit for the air moving devices inside the computer servers is needed.

Thus, embodiments of the present invention may provide advantages including, but not limited to, implementing an air moving device configurable speed limit procedure to reduce external acoustic exposure/provide noise mitigation based on the position of an interlocking door hardware that is operationally equipped to the computer server rack's acoustic rack door. The present invention can utilize a hardware management console, a managed network switch, and one or more service processors in the one or more computer servers to adjust the speed of the air moving devices in the computer servers to a configurable speed limit so that the computer server rack produces acoustic levels below a set decibel threshold. Additionally, the present invention can correlate the acoustic output of the one or more air moving devices to a configurable speed limit at which to set the one or more air moving devices based on the set decibel threshold. The present invention does not require that all advantages need to be incorporated into every embodiment of the invention.

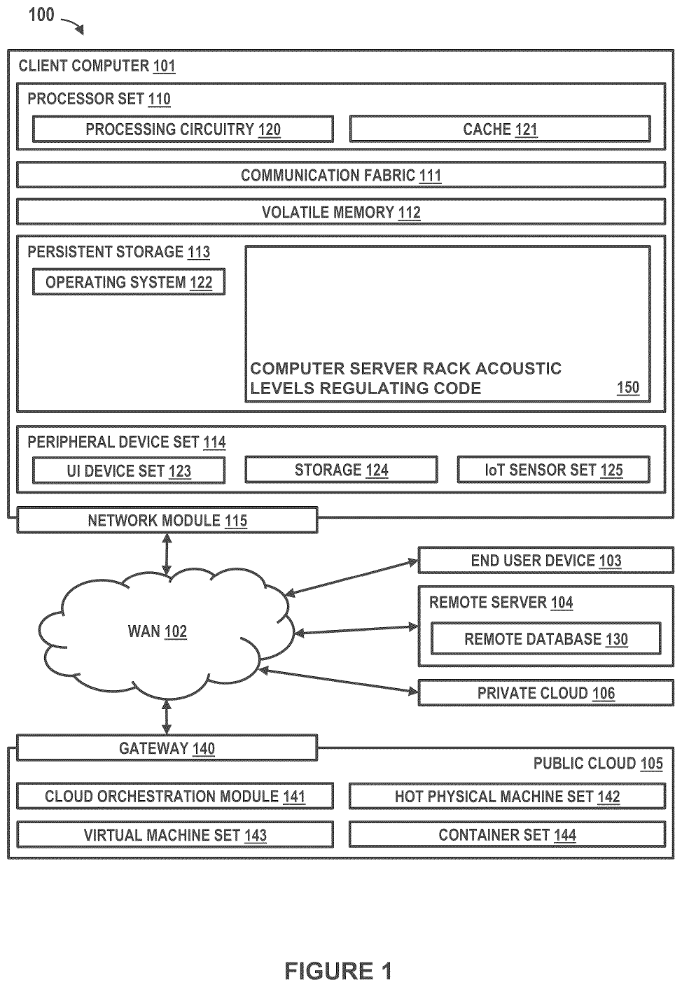

The embodiments mentioned in this paragraph are further illustrated and described below in the discussions of FIGS. 1 through 6. According to at least one embodiment, the present invention adjusts a speed of one or more air moving devices to a configurable speed limit so that the one or more computer server racks, in combination, produce an acoustic level below a set decibel threshold. The one or more air moving devices are located in one or more computer servers within the one or more computer server racks. Also, the present invention receives confirmation upon each of the one or more air moving devices running at the configurable speed limit from one or more service processors in the one or more computer servers. Furthermore, the present invention maintains the running of the one or more air moving devices at the configurable speed limit during a duration that one or more acoustic rack doors are open. The one or more acoustic rack doors are operationally coupled to the one or more computer server racks. Moreover, the present invention adjusts the speed of the one or more air moving devices back to their routine operating speeds upon receiving a lock request.

According to at least one other embodiment, adjusting the speed of the one or more air moving devices is initiated upon receiving a request to unlock the one or more acoustic rack doors or upon one or more toggle switches on the one or more service processors being toggled to an enabled position. According to at least one other embodiment, an interlocking door hardware is operationally coupled to each of the one or more acoustic rack doors. According to at least one other embodiment, the lock request is generated upon all of the one or more acoustic rack doors closing or upon all of the one or more toggle switches being toggled to a disabled position. According to at least one other embodiment, the present invention unlocks the one or more acoustic rack doors by changing a position of the interlocking door hardware to an unlocked position upon receiving confirmation of the one or more air moving devices running at the configurable speed limit. According to at least one other embodiment, the present invention correlates a speed of the one or more air moving devices to an acoustic output of the one or more computer servers to determine the speed at which to set the configurable speed limit in order to comply with the set decibel threshold. According to at least one other embodiment, the present invention comprises a communication flow through a hardware management console, a managed network switch, the one or more service processors, and an interlocking door hardware.

The present invention may be a system, a method, and/or a computer program product at any possible technical detail level of integration. The computer program product may include a computer-readable storage medium (or media) having computer-readable program instructions thereon for causing a processor to carry out aspects of the present invention.

Various aspects of the present disclosure are described by narrative text, flowcharts, block diagrams of computer systems, and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer-readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer-readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation, or garbage collection, but this does not render the storage device as transitory because the data is not transitory while it is stored.

The following described exemplary embodiments provide a system, method, and program product to adjust a speed of one or more air moving devices to a configurable speed limit so that the one or more computer server racks, in combination, produce an acoustic level below a set decibel threshold, wherein the one or more air moving devices are located in one or more computer servers within the one or more computer server racks, receive confirmation upon each of the one or more air moving devices running at the configurable speed limit from one or more service processors in the one or more computer servers, maintain the running of the one or more air moving devices at the configurable speed limit during a duration that one or more acoustic rack doors are open, wherein the one or more acoustic rack doors are operationally coupled to the one or more computer server racks, and adjust the speed of the one or more air moving devices back to their routine operating speeds upon receiving a lock request.

Referring to FIG. 1, an exemplary networked computer environment 100 is depicted, according to at least one embodiment. Computing environment 100 contains an example of an environment for the execution of at least some of the computer code involved in performing the inventive methods, such as computer server rack acoustic levels regulating code 150, also referred to as “computer server rack acoustic levels regulating program 150”, or “the program 150”. In addition to code block 150 computing environment 100 includes, for example, computer 101, wide area network (WAN) 102, end-user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and code block 150, as identified above), peripheral device set 114 (including user interface (UI), device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

COMPUTER 101 may take the form of a desktop computer, laptop computer, tablet computer, smart phone, smart watch or other wearable computer, mainframe computer, quantum computer, or any other form of computer or mobile device now known or to be developed in the future that is capable of running a program, accessing a network or querying a database, such as remote database 130. The database 130 may be a digital repository capable of data storage and data retrieval. The database 130 can be present in the remote server 104 and/or any other location in the network 102. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off-chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby affect a computer-implemented method, such that the instructions thus executed will instantiate the methods specified in flowcharts and/or narrative descriptions of computer-implemented methods included in this document (collectively referred to as “the inventive methods”). These computer-readable program instructions are stored in various types of computer-readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in code block 150 in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up busses, bridges, physical input/output ports, and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, the volatile memory is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read-only memory (ROM), but typically at least a portion of the persistent storage allows writing of data, deletion of data, and re-writing of data. Some familiar forms of persistent storage include magnetic disks and solid-state storage devices. Operating system 122 may take several forms, such as various known proprietary operating systems or open-source Portable Operating System Interface type operating systems that employ a kernel. The code included in code block 150 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector. Additionally, IoT sensor set 125 may comprise contact sensors and/or pressure sensors.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer-readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers, and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer, and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs, and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community, or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

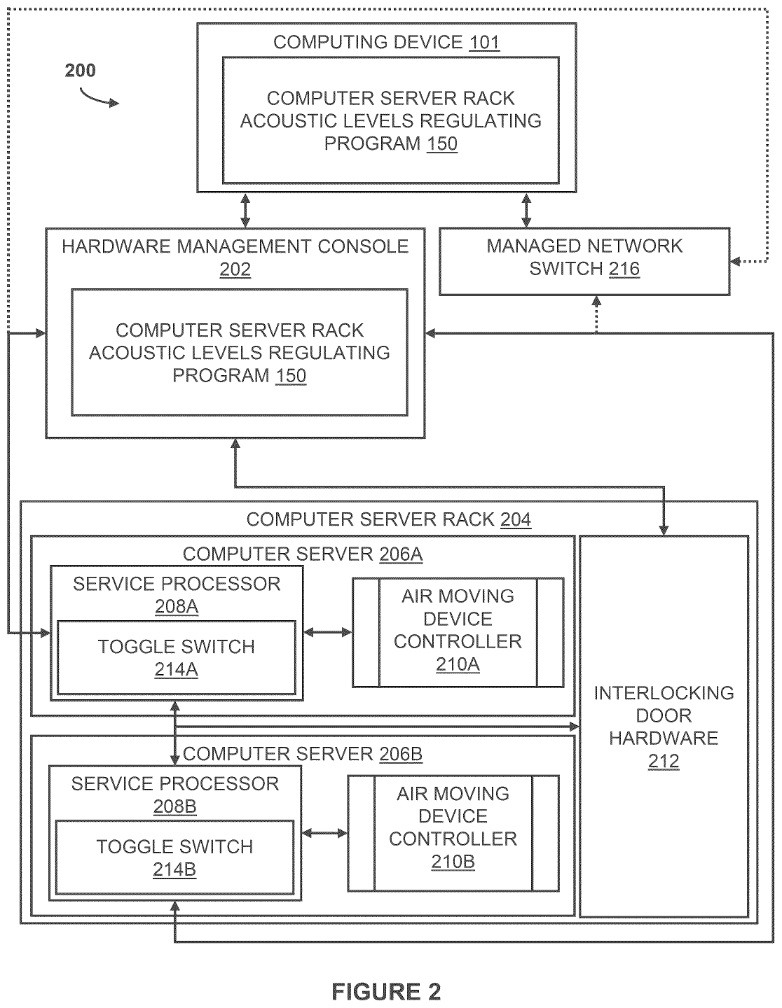

Referring to FIG. 2, a high-level partial block diagram of the components of a computer server rack acoustic levels regulation system 200, is depicted, according to at least one embodiment. FIG. 2 may include client computing device 101, a central hardware management console (“HMC”) 202, a computer server rack 204, and a managed network switch 216, interconnected via communication network 102. For illustrative purposes, an embodiment of a system 200 with one computer server rack 204 is detailed. In at least one embodiment, the system 200 may comprise more than one computer server rack 204. Client computing device 101 may be enabled to communicate with the central hardware management console 202 via the communication network 102, such as through the use of a service processor GUI, such as an Intelligent Platform Management Interface (“IPMI”), or through the use of an HMC GUI, such as Advanced System Management Interface (“ASMI”). The HMC 202 can configure and control one or more computer servers 206A, 206B within one or more computer server racks 204. The HMC 202 may be enabled to host and run computer server rack acoustic levels regulating program 150, as well as communicate with the computing device 101 and the service processors 208A, 208B in the one or more computer servers 206A, 206B. Additionally, the HMC 202 may be enabled to communicate with interlocking door hardware 212 to determine the state of the interlocking door hardware 212, i.e., locked, preparing to unlock, and unlocked. The HMC 202 may communicate with the interlocking door hardware 212 through hypertext transfer protocol secure (“HTTPS”), inter-integrated circuit (“I²C”) bus, general-purpose input/output (“GPIO”)/local inter-process communication (“LPC”), Bluetooth connections, etc.

The managed network switch 216 may be enabled to communicate with the one or more computer server racks 204, such as to configure and control the one or more managed server racks 204. The managed network switch 216 may be enabled to communicate with the computing device 101 and the service processors 208A, 208B in the one or more computer servers 206A, 206B. In at least one embodiment, the managed network switch 216 may be separate from the computer server rack 204, such as in a different cabinet/rack. In at least one embodiment, the managed network switch 216 may be comprised within the computer server rack 204.

The computer server rack 204 may comprise one or more computer servers 206A, 206B, such as IBM™ POWER™ Servers, IBM™ Z Mainframe Servers, IBM™ LinuxONE servers, etc. (IBM™ and all IBM™-based trademarks and logos are trademarks or registered trademarks of IBM Corporation, and/or its affiliates), interlocking door hardware 212, and an acoustic rack door, such as an IBM™ z16 Acoustic Door, not shown. In at least one embodiment, the computer server rack 204 may comprise information technology equipment in addition to, or instead of, the one or more computer servers 206A, 206B. For example, the computer server rack 204 may comprise one or more storage drawers. Also, for example, the computer server rack 204 may comprise one or more I/O drawers, not shown. In such embodiments, the service processors 208A, 208B may notify the respective I/O drawers to adjust the speed of the air moving devices to the configurable speed limit. The service processors 208A, 208B may communicate with the I/O drawers through a PowerVM™ hypervisor (PowerVM™ and all PowerVM™-based trademarks and logos are trademarks or registered trademarks of IBM Corporation, and/or its affiliates), an IBM™ z/VM hypervisor, etc. In at least one embodiment, the I/O drawer(s) and similar non-processor elements may be separate from the computer server rack 204, such as in a different cabinet/rack. Additionally, in at least one embodiment, the computer server rack 204 is not limited to IBM™ brand equipment.

The acoustic rack door can be operationally coupled to the interlocking door hardware 212. The acoustic rack door may be operationally coupled to the computer server rack 204, and is used to open and close the computer server rack 204. The acoustic rack door attenuates/mitigates the noise produced inside the computer server rack 204 by reducing/muffling the level of acoustic levels that internally leak from the computer server rack 204 to its external physical surroundings. The acoustic rack door can be interlocked electronically with the service processors 208A, 208B such that the rack door cannot be opened when the interlocking door hardware 212 is not in an unlocked position, i.e. when the computer server rack 204 is producing acoustic levels above a set decibel threshold, such as a threshold set at one hundred (100) decibels dB (A), ninety (90) decibels dB (A), etc.

The computer servers 206A, 206B may comprise a service processor 208A, 208B, such as a baseboard management controller (“BMC”) or a field service processor (“FSP”), an air moving device controller module 210A, 210B, and one or more air moving devices, such as a fan and/or a blower, not shown. The service processors 208A, 208B may comprise toggle switches 214A, 214B, such as a digital toggle switch. The digital toggle switches 214A, 214B may be enabled and disabled through the IPMI. The service processors 208A, 208B can communicate with the air moving device controller modules 210A, 210B, respectively, to adjust the speed of the one or more air moving devices in the computer servers 206A, 206B, respectively, such as to decrease a speed, maintain a current speed, or increase a speed of the air moving devices. The service processors, 208A, 208B can communicate with the respective air moving device controller modules 210A, 210B through a connection established through the I/O ports of the services processors 208A, 208B and the I/O ports of the respective air moving device controller modules 210A, 210B. The air moving device controller modules 210A, 210B can determine, adjust, and maintain the speed of the air moving devices via pulse-width modulation (“PWM”). Also, the service processors 208A, 208B can communicate with the interlocking door hardware 212, such as to send commands to change the locking position of the interlocking door hardware 212.

The interlocking door hardware 212 may be an electronic locking device 212 that may be set in one of three positions: (1) position one; (2) position two; and (3) position three. The position of the three-position lock 212 determines whether the acoustic rack door is locked or unlocked. Additionally, the position of the three-position lock 212 corresponds to the speed of the air moving device(s) within the computer servers 206A, 208B, etc. In position one, the acoustic rack door is locked, and thus, cannot be opened. Also, position one reflects that the air moving devices are running at their operational speeds. In position two, i.e. the intermediary position, the acoustic rack door remains locked and thus, cannot be opened. Also, position two reflects that the speed of the air moving devices is in the process of being adjusted to the speed that would result in the production of acoustic levels in the computer server rack 204 equal to or lower than the set decibel threshold, to prepare for the unlocking of the acoustic rack door. In position three, the acoustic rack door is unlocked, and thus, can be opened. Also, position three reflects that the speed of the air moving devices is currently at the speed that results in the production of acoustic levels in the computer server rack 204 equal to or lower than the set decibel threshold. In at least one embodiment, the interlocking door hardware 212 may be an electronic locking device 212 that may be set in fewer than three positions, such as two positions, for example, an unlocked position and a locked position. In at least one embodiment, the interlocking door hardware 212 may be an electronic locking device 212 that may be set in greater than three positions, for example, four, five, etc. Additionally, the interlocking door hardware 212 can store rack identifier information comprising the location and the name of the computer server rack 204 that the interlocking door hardware 212 is operationally coupled to. Moreover, the interlocking door hardware 212 can comprise location and name identification information related to the interlocking door hardware 212 itself.

The interlocking door hardware 212 may send and receive requests/alerts/notifications through any of the following forms of communication flow: (1) communication with the HMC 202, and the HMC 202 can communicate with the service processors 208A, 208B; (2) communication with all the service processors 208A, 208B in the system 200 through the communication network 102, utilizing a server rack's 204 rack identifier information to determine which computer server rack, for example, 204, the service processors are a part of; (3) communication with the service processors 208A, 208B in the computer server rack 204 that the interlocking door hardware 212 is operationally coupled to through a local rack management network; (4) communication with one service processor, either 208A or 208B, in the computer server rack 204, and the service processor, for example, 208A, communicates with the other service processors, for example, 208B, in the computer server rack 204; (5) communication with one service processor, either 208A or 208B, in the computer server rack 204, and the service processor, for example, 208A, communicates with the HMC 202, which communicates with the other service processors, for example, 208B; and (6) communication with one service processor, either 208A or 208B, in the computer server rack 204, and the service processor, for example, 208A, communicates with the managed network switch 216, which communicates with the other service processors, for example, 208B.

Additionally, the interlocking door hardware 212 can communicate to the service processors 208A, 208B, and/or the HMC 202 when the acoustic rack door is open or closed. Upon the contact sensors 125, attached to the acoustic rack door and the computer server rack 204, separating, the interlocking door hardware 212 may communicate that the acoustic rack door is open. Upon the contact sensors 125 coming back into contact, the interlocking door hardware 212 may communicate that the acoustic rack door is closed. In at least one embodiment, the service processors 208A, 208B, and/or the HMC 202 may determine that the acoustic rack door is open upon a change in the air pressure signal in computer server rack 204 using air pressure sensors 125. In at least one embodiment, service processors 208A, 208B, and/or the HMC 202 may determine that the acoustic rack door is closed upon the air pressure signal in the computer server rack 204 returning to normal pressure levels using the air pressure sensors 125.

It should be understood that additional system architecture directed to certain aspects of the operation that are not required for an understanding of the present invention, such as nodes, frames, cages, switch networks, disk devices, rack mount, mounting slots, etc., has not been depicted for case of illustration. It may be appreciated that FIG. 2 provides only an illustration of one implementation and does not imply any limitations with regard to the environments in which different embodiments may be implemented. Many modifications to the depicted environments may be made based on design and implementation requirements.

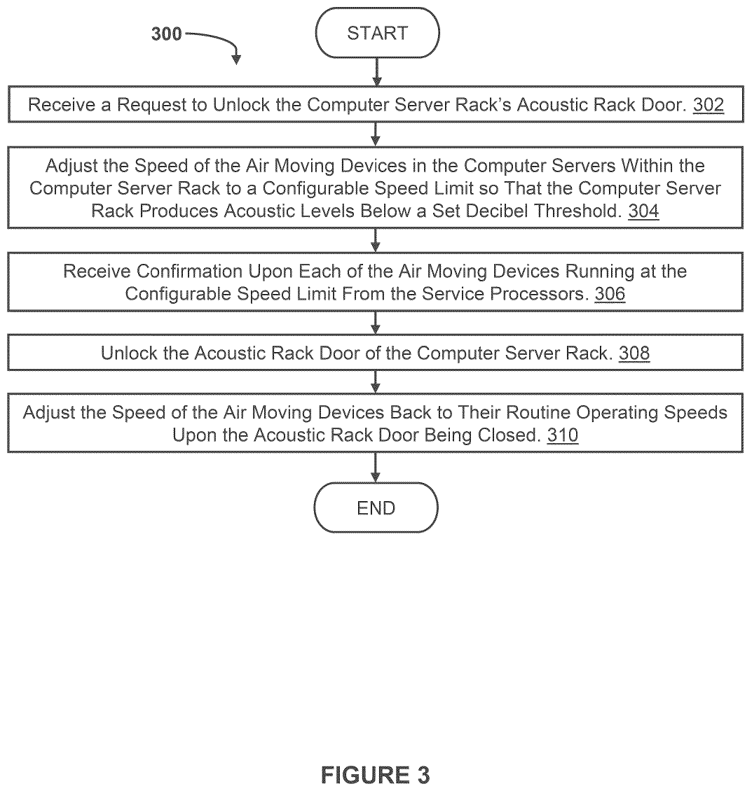

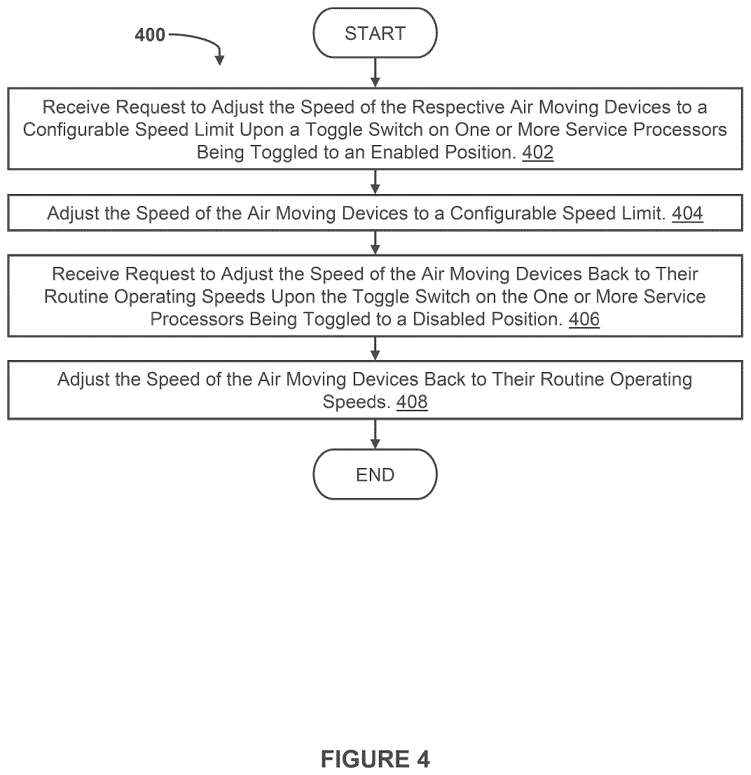

According to the present embodiment, the computer server rack acoustic levels regulating program 150 may be a program capable of adjusting a speed of one or more air moving devices to a configurable speed limit so that the one or more computer server racks, in combination, produce an acoustic level below a set decibel threshold, wherein the one or more air moving devices are located in one or more computer servers within the one or more computer server racks. Also, the program 150 may be a program capable of receiving confirmation upon each of the one or more air moving devices running at the configurable speed limit from one or more service processors in the one or more computer servers. Additionally, the program 150 may be a program capable of maintaining the running of the one or more air moving devices at the configurable speed limit during a duration that one or more acoustic rack doors are open, wherein the one or more acoustic rack doors are operationally coupled to the one or more computer server racks. Moreover, the program 150 may be a program capable of adjusting the speed of the one or more air moving devices back to their routine operating speeds upon receiving a lock request. The program 150 may be located on the client computing device 101, the HMC 202, remote server 104, on any other device located within network 102, or on any combination of the devices located within network 102. Furthermore, the program 150 may be distributed in its operation over multiple devices, such as client computing device 101 and remote server 104 or client computing device 101 and HMC 202. The program 150 is explained in further detail below with respect to FIGS. 3 and 4.

Referring now to FIG. 3, an operational flowchart illustrating a computer server rack acoustic levels regulating process 300 is depicted according to at least one embodiment. At 302, the program 150 receives a request from the central hardware management console (“HMC”) 202 to unlock the computer server rack's 204 acoustic rack door. The request may be received directly from the HMC 202 or through the HMC 202 as initiated by the client computing device 101. In at least one embodiment, the request may be received through the managed network switch 216 as initiated by the client computing device 101. As previously stated, while the interlocking door hardware 212 is set to position one, the acoustic rack door is locked and the air moving devices are running at their routine operating speeds. Additionally, the program 150 logs the unlock request as an event, along with any error conditions encountered, in one or more locations, such as the HMC 202 system log or individually in each service processor 208A, 208B. Along with the event being logged, a hazard warning message can be displayed at the HMC 202 GUI along with an auditory warning message through UI device set 123, with a confirmation message that the system 200 will proceed with adjusting the speed of the respective air moving devices to a configurable speed limit so that the computer server rack's 204 acoustic rack door can be opened.

At 304, the program 150 adjusts the speed of the air moving devices in the computer servers 206A, 206B to a configurable speed limit so that the computer server rack 204 produces acoustic levels below a set decibel threshold. Upon receiving the unlock request, the program 150 can change the position of the interlocking door hardware 212 to position two. Additionally, upon the interlocking door hardware 212 being set to position two, the service processors, 208A, 208B can adjust the speed of the one or more air moving devices through the respective air moving device controller modules 210A, 210B via PWM.

A set decibel threshold can comprise an overall decibel dB (A) level lower than one hundred (100), ninety (90), etc. In other words, the decibel levels produced by each computer server 206A, 206B in the computer server rack 204 will be less than or equal to the set decibel threshold decibel. As such, the decibel levels produced by the computer severs 206A, 206B, in combination, will be less than or equal to the set decibel threshold decibel. Each computer server 206A, 206B, and other equipment, installed in in the computer server rack 204, may operate at the same decibel level or a different decibel level. The set decibel threshold can be a user-configurable parameter, for example, set through the ASMI that is accessed through a secure screen option of the HMC 202 or of the client computing device 101.

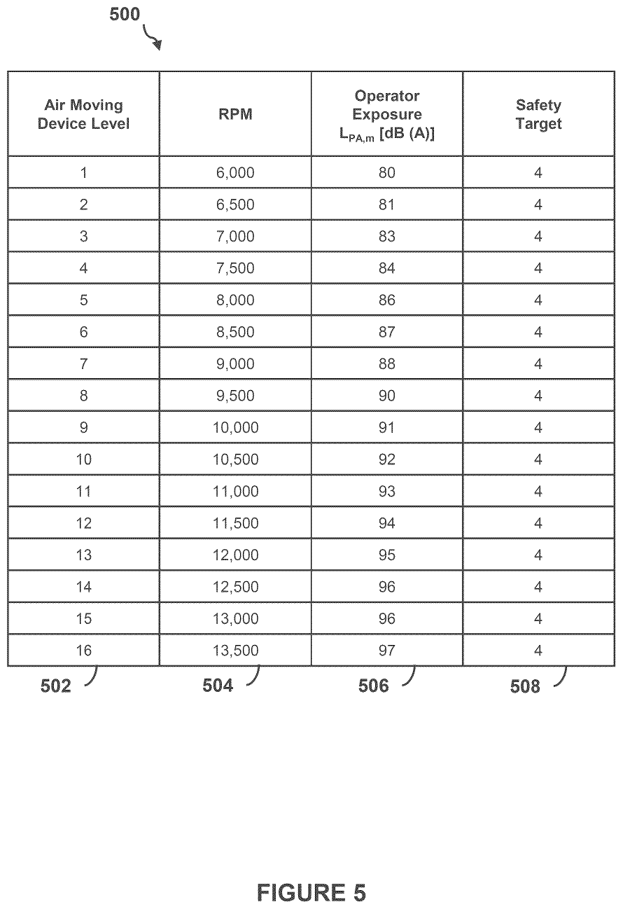

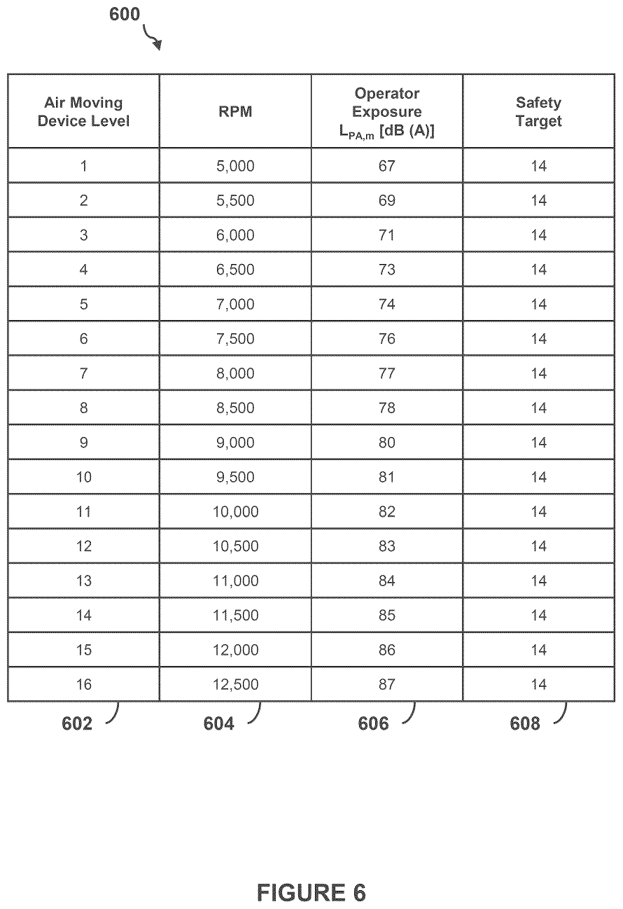

The program 150 can correlate the speed of the air moving devices to the acoustic output of the computer servers 206A, 206B, together, as well as individually. The service processors 208A, 208B can individually comprise a lookup table(s) 500, 600 depicting the one or more air moving devices’, in their respective computer servers 206A, 206B, acoustic output during various speeds at which the air moving devices can operate, as depicted in FIGS. 5 and 6. A lookup table(s) 500, 600 can comprise an air device level 502, 602 that corresponds to a speed represented by revolutions per minute (“RPM”) 504, 604, an operator exposure that represents the highest recorded sound pressure level (“SPL”) 506, 606 produced by the air moving devices, and a safety target 508, 608. The highest recorded SPL references the SPL at a known location/distance from the source(s) of sound, i.e. a specific point in space relative to the source(s). In at least one embodiment, the highest recorded SPL specifies the sound level at the front and rear service position where an operator is expected to be located, based on International Standards, etc., while interacting with a computer server rack 204. The safety target 508, 608 can specify the air moving device level 502, 602 at which the air moving devices would produce an operator exposure level 506, 606 equal to or lower than the set decibel threshold. For example, the safety target 508, 608 is listed as four (4) in FIG. 5 and fourteen (14) in FIG. 6, whereby the set decibel threshold is set at 85 dB (A), which represents the sound threshold at which exposure can result in permanent hearing damage as recognized by the Occupational Safety and Health Administration (“OHSA”). In FIG. 5, the listed safety target 508 corresponds with air moving device level 502 four (4), at which the operator exposure level 506 would be eighty-four (84) dB (A). In FIG. 6, the listed safety target 508 corresponds with air moving device level 602 fourteen (1), at which the operator exposure level 606 would be eighty-five (85) dB (A). Additionally, the lookup table(s) 500, 600 may exist in a format not necessarily as shown, such as with a greater number of rows and/or columns, or a lesser number of rows and/or columns.

The program 150 can adjust the speeds of the air moving devices using the values in the lookup table(s) 500, 600 to correlate a speed of the air moving devices to an acoustic output (decibels). For example, in an embodiment where the computer server rack 204 comprises one computer server, 206A or 206B, and the set decibel threshold is eighty (80) decibels, the program 150 may adjust the speed of each air moving device to a value that produces an acoustic output equal to the set decibel threshold. More specifically, upon receiving an unlock request, the program 150 may access the configuration inventory of the equipment in the computer server rack 204 for which the unlock request was issued. For each air moving device in the inventory, the program 150 may find its associated current air moving device level 502 in the table 500 to determine the air moving devices' corresponding speed 504 and operator exposure level 506. The program 150 may correlate the set decibel threshold to a value in the operator exposure column 506, for example, 80 dB (A), and then correlate the value in the operator exposure column 506 to both a corresponding speed 504 and an air moving device level 502. The program 150 may send instructions to the respective air moving device controller modules 210A, 210B to reduce the speed of the air moving devices to the speed 504 that corresponds to the correlated operator exposure level 506. The respective air moving device controller modules 210A, 210B may change the air moving devices' air moving device level 502 to the level 502 which corresponds to the operator exposure value 506. Thus, the computer server rack 204 would produce an acoustic level of eighty (80) decibels. Additionally, in at least one embodiment, the available capacity and/or performance of the system 200 may need to be scaled/throttled to allow for the reduced cooling introduced by the decrease in air moving device speed.

In embodiments whereby the computer server rack 204 comprises multiple computer servers 206A, 206B, the program 150 may adjust the speed of each computer server's 206A, 206B air moving devices individually based on the acoustic output listed in their lookup tables 500, 600. For example, in an embodiment in which the computer server rack 204 comprises two computer servers, 206A and 206B, and the set decibel threshold is eighty-two (82) decibels, the program 150 may adjust the speed 504, 604 of each air moving device to a value that results in each computer server, 206A, 206B producing an acoustic output 506, 606 less than the set decibel threshold, such as eighty (80) dB (A). Thus, the combination of the acoustic output from the computer servers 206A, 206B would result in the computer server rack 204 producing an acoustic level of eighty-two (82) decibels. Therefore, as the number of computer servers, 206A, 206B, etc., in a computer server rack 204 increases, the lower the speeds of the air moving devices would be set so that the total acoustic level produced by the computer server rack 204 can comply with the set decibel threshold.

Furthermore, in embodiments whereby the system 200 comprises more than one computer server rack 204, the program 150 may reduce the speed of the air moving devices in the computer servers 206A, 206B within the computer server rack 204 based on each of the computer server rack's 204 contributions to acoustic exposure. For example, a computer server rack 204 emitting a greater magnitude of emission would have a greater reduction of speed for the air moving devices in their respective computer servers 206A, 206B, than a computer server rack emitting a lesser magnitude of emission.

Additionally, during its calculation of the configurable speed limit, the program 150 implements a buffer, for example, three (3) dB, as a margin of safety to ensure the maximum decibel level produced by the air moving devices complies with the set decibel threshold. Moreover, the program 150 may maintain the configurable speed limit of the air moving devices so that the computer server rack's 204 acoustic level production is constant throughout the duration that the acoustic rack door is open.

At 306, the program 150 receives a confirmation upon each of the air moving devices running at the configurable speed limit from the service processors 208A, 208B. Upon the service processors 208A, 208B confirming that the air moving devices are running at the configurable speed limit, the service processors 208A, 208B can send a confirmation alert/notification to the program 150.

At 308, the program 150 unlocks the acoustic rack door of the computer server rack 204 by changing the position of the interlocking door hardware 212 to position three, thus, enabling the acoustic rack door of the computer server rack 204 to be manually opened. The program 150 can display a visual alert on the HMC 202 GUI and output an auditory alert through the UI device set 123 indicating that the acoustic rack door is unlocked.

At 310, the program 150 adjusts the speed of the air moving devices back to their routine operating speeds upon the acoustic rack door being closed. Upon the acoustic rack door being closed, the HMC 202 or the managed network switch 216 can send a lock request to the program 150. Upon receiving the lock request, the program 150 can change the position of the interlocking door hardware 212 back to position one. Additionally, upon the interlocking door hardware 212 being set to position one, the service processors, 208A, 208B can adjust the speed of the one or more air moving devices through the respective air moving device controller modules 210A, 210B back to their routine operating speeds. Additionally, the program 150 logs the lock request as an event, along with any error conditions encountered, in one or more locations, as previously mentioned. Along with the event being logged, a hazard warning message can be displayed at the HMC 202 GUI along with an auditory warning message through UI device set 123, with a confirmation message that the system 200 will proceed with adjusting the speed of the respective air moving devices back to their routine operating speeds and that the interlocking door hardware 212 is now locked.

In at least one embodiment, the program 150 may allow for an override of the computer server rack acoustic levels regulating process 300. The override may be initiated through the manual unlocking of the interlocking door hardware 212, such as by the use of a physical key. Thus, the acoustic rack door may be physically opened without the involvement of the program 150, such as to enable emergency access to the hardware when the initiation and performance of the process 300 would be, for example, inhibitive or obstructive.

Referring now to FIG. 4, an operational flowchart illustrating an alternate computer server rack acoustic levels regulating process 400 is depicted according to at least one embodiment. In this embodiment, the interlocking door hardware 212 is not present. However, the present invention provides noise mitigation benefits through a combination of a digital toggle switch 214A, 214B on each service processor 208A, 208B, and the ASMI. The communication path between each service processor 208A, 208B, and the HMC 202 is as discussed previously with reference to FIG. 3.

At 402, the program 150 receives a request to adjust the speed of the respective air moving devices to a configurable speed limit upon a toggle switch(-es) 214A, 214B on one or more service processors 208A, 208B being toggled to an enabled position. A customer can access each service processor 208A, 208B on each computer server 206A, 206B in a computer server rack 204. The customer can toggle each toggle switch 214A, 214B to an enabled position. Alternatively, the customer can enable the toggle switch(-es) 214A, 214B to an enabled position virtually through the secure screen option of the HMC 202. In either case, the program 150 logs the access as an event, along with any error conditions encountered, in one or more locations, as previously mentioned. Along with the event being logged, a hazard warning message can be displayed at the HMC 202 GUI, with a confirmation request that the customer wishes to proceed with adjusting the speed of the respective air moving devices to a configurable speed limit that results in the computer server rack 204 producing acoustic levels below a set decibel threshold.

At 404, the program 150 adjusts the speed of the air moving devices to the configurable speed limit, after which the acoustic rack door can be opened. The program 150 adjusts the speed of the air moving devices to the configurable speed limit in the same manner as in step 304, except that program 150 does not set/change the locking status of the interlocking door hardware 212 because of the absence of the interlocking door hardware 212.

At 406, the program 150 receives a request to adjust the speed of the respective air moving devices back to their routine operating speeds upon the toggle switch(-es) 214A, 214B on the one or more service processors 208A, 208B being toggled to a disabled position. Following completion of the service event, the customer closes and latches the acoustic rack door. The toggle switch(-es) 214A, 214B may be toggled to a disabled position in the same manner as they were toggled to an enabled position in step 402. Again, the program 150 logs the service event along with any error conditions encountered.

At 408, the program 150 adjusts the speed of the air moving devices back to their routine operating speeds. The program 150 adjusts the speed of the air moving devices back to their routine operating speeds in the same manner as in step 310, except that program 150 does not set/change the locking status of the interlocking door hardware 212 because of the absence of the interlocking door hardware 212.

It can be additionally noted that even when the interlocking door hardware 212 is present, as an added safeguard, the option to enable adjusting the speed of the air moving devices must be toggled from the ASMI before it becomes operational.

It may be appreciated that FIGS. 2 through 6 provide only an illustration of one implementation and do not imply any limitations with regard to how different embodiments may be implemented. Many modifications to the depicted environments may be made based on design and implementation requirements.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A computer-implemented method for regulating acoustic levels produced within one or more computer server racks, the method comprising:
adjusting a speed of one or more air moving devices to a configurable speed limit so that the one or more computer server racks in combination produce an acoustic level below a set decibel threshold, wherein the one or more air moving devices are located in one or more computer servers within the one or more computer server racks;
receiving confirmation upon each of the one or more air moving devices running at the configurable speed limit from one or more service processors in the one or more computer servers;
maintaining the running of the one or more air moving devices at the configurable speed limit during a duration that one or more acoustic rack doors are open, wherein the one or more acoustic rack doors are operationally coupled to the one or more computer server racks; and
adjusting the speed of the one or more air moving devices back to their routine operating speeds upon receiving a lock request.

2. The method of claim 1, wherein the adjusting of the speed of the one or more air moving devices is initiated upon receiving a request to unlock the one or more acoustic rack doors or upon one or more toggle switches on the one or more service processors being toggled to an enabled position.

3. The method of claim 1, wherein an interlocking door hardware is operationally coupled to each of the one or more acoustic rack doors.

4. The method of claim 2, wherein the lock request is generated upon all of the one or more acoustic rack doors closing or upon all of the one or more toggle switches being toggled to a disabled position.

5. The method of claim 3, the method further comprising:
unlocking the one or more acoustic rack doors by changing a position of the interlocking door hardware to an unlocked position upon receiving confirmation of the one or more air moving devices running at the configurable speed limit.

6. The method of claim 1, the method further comprising:
correlating a speed of the one or more air moving devices to an acoustic output of the one or more computer servers to determine the speed at which to set the configurable speed limit in order to comply with the set decibel threshold.

7. The method of claim 1, wherein the method comprises a communication flow through a hardware management console, a managed network switch, the one or more service processors, and an interlocking door hardware.

8. A computer system for regulating acoustic levels produced within one or more computer server racks, the computer system comprising:
one or more processors, one or more computer-readable memories, one or more computer-readable tangible storage medium, and program instructions stored on at least one of the one or more tangible storage medium for execution by at least one of the one or more processors via at least one of the one or more memories, wherein the computer system is capable of performing a method comprising:
adjusting a speed of one or more air moving devices to a configurable speed limit so that the one or more computer server racks, in combination, produce an acoustic level below a set decibel threshold, wherein the one or more air moving devices are located in one or more computer servers within the one or more computer server racks;
receiving confirmation upon each of the one or more air moving devices running at the configurable speed limit from one or more service processors in the one or more computer servers;
maintaining the running of the one or more air moving devices at the configurable speed limit during a duration that one or more acoustic rack doors are open, wherein the one or more acoustic rack doors are operationally coupled to the one or more computer server racks; and
adjusting the speed of the one or more air moving devices back to their routine operating speeds upon receiving a lock request.

9. The computer system of claim 8, wherein adjusting the speed of the one or more air moving devices is initiated upon receiving a request to unlock the one or more acoustic rack doors or upon one or more toggle switches on the one or more service processors being toggled to an enabled position.

10. The computer system of claim 8, wherein an interlocking door hardware is operationally coupled to each of the one or more acoustic rack doors.

11. The computer system of claim 9, wherein the lock request is generated upon all of the one or more acoustic rack doors closing or upon all of the one or more toggle switches being toggled to a disabled position.

12. The computer system of claim 10, the method further comprising:
unlocking the one or more acoustic rack doors by changing a position of the interlocking door hardware to an unlocked position upon receiving confirmation of the one or more air moving devices running at the configurable speed limit.

13. The computer system of claim 8, the method further comprising:
correlating a speed of the one or more air moving devices to an acoustic output of the one or more computer servers to determine the speed at which to set the configurable speed limit in order to comply with the set decibel threshold.

14. The computer system of claim 8, wherein the method comprises a communication flow through a hardware management console, a managed network switch, the one or more service processors, and an interlocking door hardware.

15. A computer program product for regulating acoustic levels produced within one or more computer server racks, the computer program product comprising:
one or more computer-readable tangible storage medium and program instructions stored on at least one of the one or more tangible storage medium, the program instructions executable by a processor to cause the processor to perform a method comprising:
adjusting a speed of one or more air moving devices to a configurable speed limit so that the one or more computer server racks, in combination, produce an acoustic level below a set decibel threshold, wherein the one or more air moving devices are located in one or more computer servers within the one or more computer server racks;
receiving confirmation upon each of the one or more air moving devices running at the configurable speed limit from one or more service processors in the one or more computer servers;
maintaining the running of the one or more air moving devices at the configurable speed limit during a duration that one or more acoustic rack doors are open, wherein the one or more acoustic rack doors are operationally coupled to the one or more computer server racks; and
adjusting the speed of the one or more air moving devices back to their routine operating speeds upon receiving a lock request.

16. The computer program product of claim 15, wherein adjusting the speed of the one or more air moving devices is initiated upon receiving a request to unlock the one or more acoustic rack doors or upon one or more toggle switches on the one or more service processors being toggled to an enabled position.

17. The computer program product of claim 15, wherein an interlocking door hardware is operationally coupled to each of the one or more acoustic rack doors.

18. The computer program product of claim 16, wherein the lock request is generated upon all of the one or more acoustic rack doors closing or upon all of the one or more toggle switches being toggled to a disabled position.

19. The computer program product of claim 17, the method further comprising:
unlocking the one or more acoustic rack doors by changing a position of the interlocking door hardware to an unlocked position upon receiving confirmation of the one or more air moving devices running at the configurable speed limit.

20. The computer program product of claim 15, the method further comprising:
correlating a speed of the one or more air moving devices to an acoustic output of the one or more computer servers to determine the speed at which to set the configurable speed limit in order to comply with the set decibel threshold.
